(19) United States
(12) Patent Application Publication
(10) Pub. No.: US 2026/0142631 A1
(43) Pub. Date: May 21, 2026

(54) BIAS CONTROL FOR DC COUPLED SINGLE-ENDED DISTRIBUTED AMPLIFIERS OF MULTI-STAGE AMPLIFIERS

(71) Applicant: MACOM Technology Solutions Holdings, Inc., Lowell, MA (US)

(72) Inventors: Duy P. Nguyen, San Jose, CA (US); Trong Phan, Garden Grove, CA (US); Nguyen L.K. Nguyen, Bedford, MA (US); Wayne Kennan, Palo Alto, CA (US); Stefano D'Agostino, Los Altos, CA (US); William M. Allen, Gansevoort, NY (US)

(21) Appl. No.: 18/950,697

(22) Filed: Nov. 18, 2024

(51) Int. Cl. H03F 3/45

(52) U.S. Cl. CPC H03F 3/45085; H03F 3/45475; H03F 2203/45154

(57) ABSTRACT

Amplifiers with bias control for DC coupled single-ended distributed amplifiers of multi-stage amplifiers are described herein. An example amplifier with input bias control includes a distributed amplifier cell having an input coupled to a first distributed transmission line and an output coupled to a second distributed transmission line, an input coupling network coupled between the first distributed transmission line and the input of the distributed amplifier cell, and a bias interface circuit coupled between the input coupling network and the input of the distributed amplifier cell. The amplifier can also include a bias control circuit configured to control an amplifier input bias generated by the bias interface circuit at the input of the distributed amplifier cell.

### BACKGROUND

A range of different amplifiers are known and relied upon for data communications. Differential amplifiers, as an example, are commonly used for high-speed data communications. Differential amplifiers are designed to amplify the difference between two input signals and to reject noise or interference that is present on both (i.e., common to) the input signals. Differential amplifiers are often used as the first amplifier stage in operational amplifiers, and multiple stages of differential amplifiers can be cascaded depending on design needs and the amplification application. As another example, distributed amplifiers rely in part on transmission line theory to achieve a relatively larger gain-bandwidth product than that achieved by other types of amplifier circuits. These and other types of amplifiers and amplifier stages are known, and each type of amplifier can have a different amplifier circuit configuration.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Amplifiers with new circuit topologies for gain shaping and gain control are described herein. An example amplifier with input bias control includes a distributed amplifier cell having an input coupled to a first distributed transmission line and an output coupled to a second distributed transmission line, an input coupling network coupled between the first distributed transmission line and the input of the distributed amplifier cell, and a bias interface circuit coupled between the input coupling network and the input of the distributed amplifier cell. The input coupling network can include a resistive-capacitive network, such as a resistor coupled in parallel with a capacitor. The amplifier can also be embodied as a multi-stage amplifier in some cases. The distributed amplifier cell can be coupled to an output of a variable gain amplifier stage of the multi-stage amplifier.

The amplifier can also include a bias control circuit. The bias control circuit can be configured to control an amplifier input bias generated by the bias interface circuit at the input of the distributed amplifier cell. In one example, the bias interface circuit can include an emitter follower transistor and a sink transistor coupled to a base terminal of the emitter follower transistor. The bias control circuit can be configured to control the sink transistor to set an input bias of the emitter follower transistor of the bias interface circuit. The bias control circuit is further configured to control the sink transistor to establish a potential difference across the input coupling network.

The bias control circuit can include a difference operational amplifier and a reference voltage generator in one example. An output of the reference voltage generator can be coupled to a first input of the difference operational amplifier, a common terminal of the distributed amplifier cell can be coupled to a second input of the difference operational amplifier, and an output of the difference operational amplifier can be coupled to the sink transistor.

The amplifier can also include a second distributed amplifier cell. The second distributed amplifier cell can include an input coupled to the first distributed transmission line and an output coupled to the second distributed transmission line, a second input coupling network coupled between the first distributed transmission line and the input of the second distributed amplifier cell, and a second bias interface circuit coupled between the second input coupling network and the input of the second distributed amplifier cell. The bias control circuit can be further configured to control an amplifier input bias generated by the second bias interface circuit at the input of the second distributed amplifier cell.

Another example amplifier with input bias control includes a distributed amplifier cell, an input coupling network coupled between a distributed transmission line and an input of the distributed amplifier cell, and a bias interface circuit coupled to the input of the distributed amplifier cell. The bias interface circuit can include a sink transistor coupled between the distributed transmission line and an input of the distributed amplifier cell. The amplifier can also include a bias control circuit configured to control the sink transistor to set an input bias of the distributed amplifier cell. The bias control circuit can be configured to control the sink transistor to establish a potential difference across the input coupling network in one example.

In one example, the bias control circuit includes a difference operational amplifier and a reference voltage generator, an output of the reference voltage generator is coupled to a first input of the difference operational amplifier, a common terminal of the distributed amplifier cell is coupled to a second input of the difference operational amplifier, and an output of the difference operational amplifier is coupled to the sink transistor.

The amplifier can also include a second distributed amplifier cell, a second input coupling network coupled between the distributed transmission line and an input of the second distributed amplifier cell, and a second bias interface circuit coupled between the second input coupling network and the input of the second distributed amplifier cell. The bias control circuit can also be configured to control an amplifier input bias generated by the second bias interface circuit at the input of the second distributed amplifier cell.

Another example amplifier with input bias control includes a first distributed amplifier cell and a second distributed amplifier cell, a first input coupling network coupled between a distributed transmission line and an input of the first distributed amplifier cell, a second input coupling network coupled between the distributed transmission line and an input of the second distributed amplifier cell, a first bias interface circuit coupled to the input of the first distributed amplifier cell, and a second bias interface circuit coupled to the input of the second distributed amplifier cell.

The first bias interface circuit can include a first sink transistor coupled between the distributed transmission line and the input of the first distributed amplifier cell, and the second bias interface circuit can include a second sink transistor coupled between the distributed transmission line and the input of the second distributed amplifier cell. The amplifier can also include a bias control circuit configured to control the first sink transistor to set an input bias of the first distributed amplifier cell and to control the second sink transistor to set an input bias of the second distributed amplifier cell. The bias control circuit can also be configured to control the first sink transistor to establish a potential difference across the first input coupling network and to control the second sink transistor to establish a potential difference across the second input coupling network.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example multi-stage amplifier according to various examples described herein.

FIG. 2 illustrates an example amplifier with a variable gain stage and a distributed amplifier stage according to various examples described herein.

FIG. 3 illustrates another example amplifier with a variable gain stage and a distributed amplifier stage with input bias control according to various examples described herein.

FIG. 4 illustrates an example distributed amplifier cell of the multi-stage amplifier shown in FIG. 3 with bias adjustment circuitry according to various examples described herein.

### DETAILED DESCRIPTION

Receivers, transmitters, and transceivers for emerging data communication applications rely upon amplifier circuits to transfer data signals at higher speeds. The amplifiers are often designed for broadband operation, variable gain control, and other operating characteristics. Multiple amplifier stages in a multi-stage amplifier, including a combination of differential amplifiers, distributed amplifiers, variable gain amplifiers, driver amplifiers, and other types of amplifiers, can be cascaded or connected in series depending on the design needs for a given amplifier application. It can be important to tailor and optimize the operating criteria, performance, and biasing interface among of each amplifier stage in a multi-stage amplifier.

The design of an amplifier includes the evaluation of a number of operating characteristics of the amplifier, such as amplifier biasing, gain, operating bandwidth, input and output characteristics, small signal parameters, stability, and other operating characteristics. The stability of an amplifier, as one operating characteristic, can depend on the type (e.g., semiconductor structure and materials), biasing, power, temperature, bandwidth, and other factors related to the amplifier, and it is important to evaluate the stabilization characteristics and refine the stabilization approach for each amplifier design. Appropriate amplifier biasing and inter-stage amplifier biasing in multi-stage amplifiers is also important for the operation of amplifiers.

Amplifiers with bias control for DC coupled single-ended distributed amplifiers of multi-stage amplifiers are described herein. An example amplifier with input bias control includes a distributed amplifier cell having an input coupled to a first distributed transmission line and an output coupled to a second distributed transmission line, an input coupling network coupled between the first distributed transmission line and the input of the distributed amplifier cell, and a bias interface circuit coupled between the input coupling network and the input of the distributed amplifier cell. The amplifier can also include a bias control circuit configured to control an amplifier input bias generated by the bias interface circuit at the input of the distributed amplifier cell.

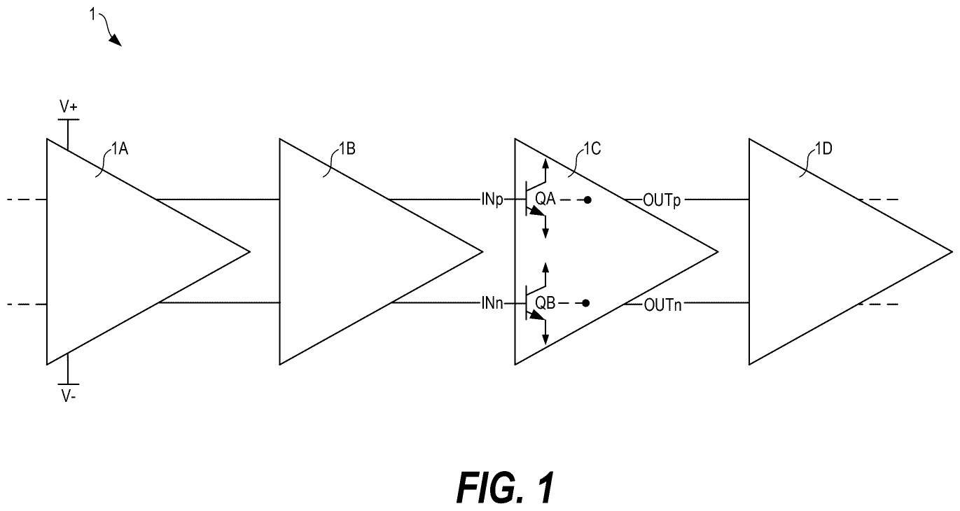

FIG. 1 illustrates an example multi-stage amplifier 1 according to various examples described herein. The multi-stage amplifier 1 can be embodied in various ways, such as using discrete components, as an integrated circuit device formed on a substrate, or as a combination of discrete components and integrated devices. The multi-stage amplifier 1 is depicted as a representative example. The multi-stage amplifier 1 is not exhaustively illustrated in FIG. 1, and the multi-stage amplifier 1 can include additional components that are not shown in some cases. The multi-stage amplifier 1 can also omit certain amplifier stages or components in other cases.

The multi-stage amplifier 1 includes a number of cascaded amplifier circuits or stages, including amplifier stages 1A-1D, among possibly others. In the cascaded configuration shown, the outputs of the amplifier stage 1A are provided as inputs to the amplifier stage 1B. The outputs of the amplifier stage 1B are provided as inputs to the amplifier stage 1C, and so on. Multi-stage amplifiers can be relied upon for increased overall gain, to tailor input or output impedances, and to achieve other objectives for certain data communications applications. Each of the amplifier stages 1A-1D is supplied with power by an upper rail voltage or potential V+ and a lower rail voltage or potential V−.

Each of the amplifier stages 1A-1D can include one or more transistor amplifiers, biasing circuitry, coupling circuitry, and related circuit components. Additionally, the transistor or transistors in each of the amplifier stages 1A-1D can be arranged or configured in different ways (e.g., distributed amplifiers, differential pair amplifiers, Darlington pair amplifiers, common collector or drain amplifiers, common emitter or source amplifiers, common base or gate amplifiers, etc.) depending on the design, objectives, and application for the multi-stage amplifier 1. The amplifier stage 1C is shown to include two transistors QA and QB, as an example, for handling a differential signal. Each of the amplifier stages 1A-1D can be designed, tailored, and optimized independently.

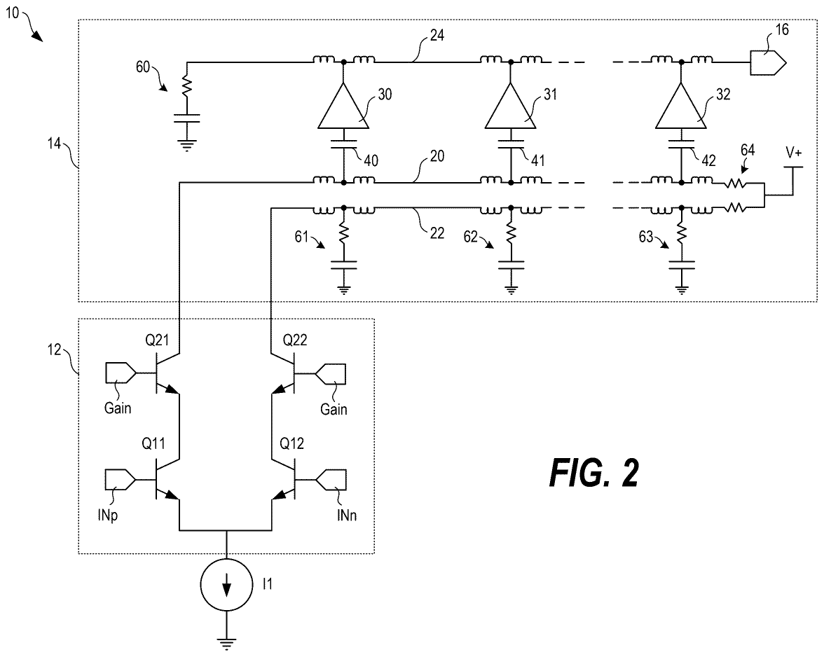

FIG. 2 illustrates an example amplifier 10 with a variable gain stage 12 and a distributed amplifier stage 14 according to various examples described herein. The amplifier circuit 10 can be embodied in various ways, such as using discrete components, as an integrated circuit device formed on a substrate, or as a combination of discrete components and integrated devices. The amplifier circuit 10 is provided as a representative example of a multi-stage amplifier. The amplifier circuit 10 is not exhaustively illustrated in FIG. 2, and the amplifier circuit 10 can include additional components that are not shown. The amplifier circuit 10 can also omit certain components in some cases.

The amplifier 10 can be used for radio frequency (RF) communications, wired communications, optical communications, or for other purposes, without limitation. The variable gain stage 12 can be implemented as one of the amplifier stages 1A-1D of the multi-stage amplifier 1 shown in FIG. 1. The gain of the variable gain stage 12 can be varied based on a control input, as described below. The distributed amplifier stage 14 can also be implemented another one of the amplifier stages 1A-1D of the multi-stage amplifier 1 shown in FIG. 1. The distributed amplifier stage 14 is implemented as a single-ended-output distributed amplifier.

In the example shown in FIG. 2, a differential output of the variable gain stage 12 is coupled to an input of the distributed amplifier stage 14. The distributed amplifier stage 14 provides a single-ended output signal for the amplifier 10 at the output 16. The amplifier circuit 10 can also be connected in other ways and to other amplifier stages in a multi-stage amplifier. The variable gain stage 12 can also be implemented as a stand-alone amplifier circuit, rather than as part of a multi-stage amplifier, in some cases. Similarly, the distributed amplifier stage 14 can be implemented as a stand-alone amplifier circuit, rather than as part of a multi-stage amplifier, in some cases.

The variable gain stage 12 includes a differential transistor pair of transistors Q11 and Q12 (also “differential transistors Q11 and Q12”), an auxiliary transistor pair of transistors Q21 and Q22 (also “auxiliary transistors Q21 and Q22”), and a current source I1 electrically coupled in the arrangement shown, among possibly other components. The distributed amplifier stage 14 includes a first distributed transmission line 20 (also “transmission line 20”), a second distributed transmission line 22 (also “transmission line 22”), a number of distributed amplifier cells 30-32, coupling capacitors 40-42, a third distributed transmission line 50 (also “transmission line 50”), and termination networks 60-64.

The emitter terminals of the differential transistors Q11 and Q12 are coupled together and to the current source I1. The current source I1 is coupled between the emitter terminals of the differential transistors Q11 and Q12 and ground or, in some cases, a lower rail voltage or potential V−. A differential input INp and INn to the variable gain stage 12 can be provided across the base terminals of the differential transistors Q11 and Q12. The emitter terminals of the auxiliary transistors Q21 and Q22 are coupled to the collectors of the differential transistors Q11 and Q12, respectively. A gain control signal for the variable gain stage 12 can be provided across the base terminals of the auxiliary transistors Q21 and Q22. The collector terminals of the auxiliary transistors Q21 and Q22 of the variable gain stage 12 are coupled to the distributed amplifier stage 14. More particularly, the collector terminals of the auxiliary transistors Q21 and Q22 are coupled to the transmission lines 20 and 22 of the distributed amplifier stage 14, respectively, and provide a differential input to the distributed amplifier stage 14 across the transmission lines 20 and 22.

The transistors Q11, Q12, Q21, and Q22 of the variable gain stage 12 are depicted as bipolar junction transistors in FIG. 2. The transistors can be embodied as field effect transistors (FETs) or other types of transistors in other cases, however, and the concepts described herein are not limited to use with amplifiers or transistors of any particular type or technology. Thus, references to the “base” or “base terminal” of a transistor include a reference to the “gate” or “gate terminal” of a FET transistor. Similarly, references to the “emitter” or “emitter terminal” of a transistor include a reference to the “source” or “source terminal” of a FET transistor, and references to the “collector” or “collector terminal” of a transistor include a reference to the “drain” or “drain terminal” of a FET transistor. Other types and configurations of amplifiers and amplifier circuits can also incorporate the amplifier gain shaping and control concepts described herein.

The current source I1 of the variable gain stage 12 is representative in FIG. 2 and can be implemented as any suitable type of current source or related biasing circuitry for the differential transistors Q11 and Q12 and the amplifier circuit 10. Examples of the current source I1 include transistor-based current mirrors, current regulators, resistors, and combinations thereof, and the current source I1 is not limited to any particular type of current source. The current source I1 can also be implemented as a variable current source in some cases.

Turning to the distributed amplifier stage 14, each of the transmission lines 20 and 22 can be embodied as transmission lines of any suitable length. The transmission lines 20 and 22 can be embodied as a pair of transmission lines, each having the same electrical length and impedance, as measured from an input end to an output of distal end. The transmission lines 20 and 22 are coupled, at input ends, to the collector terminals of the auxiliary transistors Q21 and Q22 and, at distal ends, to the upper rail voltage or potential V+. The transmission lines 20 and 22 are coupled to the upper rail voltage or potential V+ through the termination network 64, which is a pair of resistors in the example shown. From the collector terminals of the auxiliary transistors Q21 and Q22, a differential output of the variable gain stage 12 is coupled as an input to the transmission lines 20 and 22 of the distributed amplifier stage 14.

A number of taps or couplings are taken along the lengths of the transmission lines 20 and 22, preferably at equally-spaced-apart electrical lengths between them. In the example shown in FIG. 2, the coupling capacitors 40-42 are respectively coupled to different taps or couplings taken along the length of the transmission line 20. The distributed amplifier cells 30-32 are coupled, respectively, to the capacitors 40-42. Thus, the distributed amplifier cells 30-32 are also coupled to different taps or couplings taken along the lengths of the transmission line 20.

The termination networks 61-63 are respectively coupled to different taps or nodes along the length of the transmission line 22. As one example, each of the termination networks 61-63 can be embodied as a resistor coupled in series with a capacitor. Thus, the termination network 61 includes a resistor coupled at one side to the transmission line 22 and coupled at another side to a capacitor, which is also coupled to ground. The termination networks 62 and 63 are similar to the termination network 61 and are coupled at different taps along the transmission line 22.

From an electrical length standpoint, the electrical distance (e.g., measured in wavelength) between the auxiliary transistor Q21 and the coupling capacitor 40 along the transmission line 20 can be the same or substantially the same as the electrical distance between the auxiliary transistor Q22 and the termination network 61 along the transmission line 22. The electrical distance between the auxiliary transistor Q21 and the coupling capacitor 41 along the transmission line 20 can be the same as the electrical distance between the auxiliary transistor Q22 and the termination network 62 along the transmission line 22. The electrical distance between the auxiliary transistor Q21 and the coupling capacitor 42 along the transmission line 20 can be the same as the electrical distance between the auxiliary transistor Q22 and the termination network 63 along the transmission line 22. Further, the electrical distance between the coupling capacitor 40 and the coupling capacitor 41 can be the same as the electrical distance between the coupling capacitor 41 and the coupling capacitor 42.

The inputs of the distributed amplifier cells 30-32 are respectively coupled to the coupling capacitors 40-42. The outputs of the distributed amplifier cells 30-32 are respectively coupled to different taps or nodes along the length of the transmission line 24. One end of the transmission line 24 is terminated to ground through the termination network 60. Another end of the transmission line 24 provides a single-ended-output signal from the distributed amplifier stage 14 at the output 16.

The upper rail voltage V+ can be any suitable voltage. In some cases, the circuit ground can be embodied as a lower rail voltage V−, which can also be any suitable voltage or potential that is less than the upper rail voltage V+. The voltages V+ and V-can be selected, respectively, based on the target biasing voltage or voltage range for the amplifier 10. The difference in potential between the upper rail voltage V+ and ground or between the upper rail voltage V+ and the lower rail voltage V− can be any suitable potential difference based on the target biasing voltage or voltage range for the amplifier circuit 10.

Appropriate amplifier biasing and inter-stage amplifier biasing in multi-stage amplifiers is an important concern of the design of amplifiers. Referring to FIG. 2 as an example, the DC bias at the collector of the auxiliary transistor Q21 is substantially the same as the DC bias at the nodes along the transmission line 20 where the distributed amplifier cells 30-32 are coupled. However, the DC bias needed at the collector of the auxiliary transistor Q21 may be different than the DC bias needed at the inputs to the distributed amplifier cells 30-32. The need for different DC biases can make it difficult to directly couple the output of the auxiliary transistor Q21 to the inputs of the distributed amplifier cells 30-32.

To address the issue of DC bias mismatches among amplifier stages, the coupling capacitors 40-42 provide AC signal coupling and DC bias isolation between the auxiliary transistor Q21 of the variable gain stage 12 and the distributed amplifier cells 30-32 of the distributed amplifier stage 14. The coupling capacitors 40-42 permit the DC bias for the variable gain stage 12 to be separated from the DC bias for the distributed amplifier stage 14. Use of the coupling capacitors 40-42 can carry drawbacks, however, as the coupling capacitors 40-42 can be difficult to integrate with the amplifier 10 depending on the desired operating bandwidth of the amplifier 10, among other operating concerns. The coupling capacitors 40-42 can be too large to implement in an integrated way, on the same semiconductor die with the amplifier 10, depending on the desired operating bandwidth of the amplifier 10.

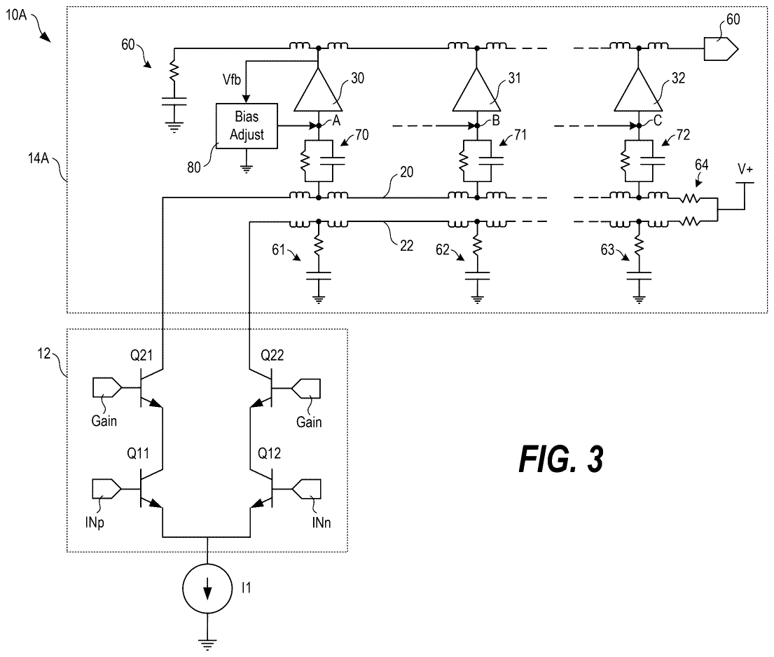

FIG. 3 illustrates another example amplifier 10A with the variable gain stage 12 and a distributed amplifier stage 14A with input bias control according to various examples described herein. The amplifier circuit 10A can be embodied in various ways, such as using discrete components, as an integrated circuit device formed on a substrate, or as a combination of discrete components and integrated devices. The amplifier circuit 10A is provided as a representative example of a multi-stage amplifier. The amplifier circuit 10A is not exhaustively illustrated in FIG. 3, and the amplifier circuit 10A can include additional components that are not shown. The amplifier circuit 10A can also omit certain components in some cases.

The amplifier 10A can be used for RF communications, wired communications, optical communications, or for other purposes, without limitation. The variable gain stage 12 can be implemented as one of the amplifier stages 1A-1D of the multi-stage amplifier 1 shown in FIG. 1. The distributed amplifier stage 14A can also be implemented another one of the amplifier stages 1A-1D of the multi-stage amplifier 1 shown in FIG. 1. The distributed amplifier stage 14A is implemented as a single-ended-output distributed amplifier.

The distributed amplifier stage 14A in FIG. 3 is different than the distributed amplifier stage 14 shown in FIG. 2. More particularly, the distributed amplifier cells 30-32 in the distributed amplifier stage 14A are DC coupled, rather than AC coupled, to the transmission line 20. The coupling capacitors 40-42 in the distributed amplifier stage 14 shown in FIG. 2 are replaced with the input coupling networks 70-72, respectively, as shown in FIG. 3. Each of the input coupling networks 70-72 is embodied as a parallel arrangement of a resistor with a capacitor. The input coupling networks 70-72 can also be embodied as other arrangements of one or more resistors and one or more capacitors in other cases.

The input coupling networks 70-72 provide two signal paths between the transmission line 20 and the distributed amplifier cells 30-32, including a resistive path for lower frequencies down to direct current (e.g., down to DC) and a capacitive path for higher frequencies. Overall, the resistors in the input coupling networks 70-72 permit DC coupling between the distributed amplifier cells 30-32 and the transmission line 20. The resistance of the resistors and the capacitance of the capacitors in the input coupling networks 70-72 can be selected for the desired low and high frequency performance and the overall operating bandwidth of the amplifier 10A. Mostly, the inclusion of the resistive path in the input coupling networks 70-72 facilitates lower frequency operation of the distributed amplifier stage 14A and the amplifier 10A.

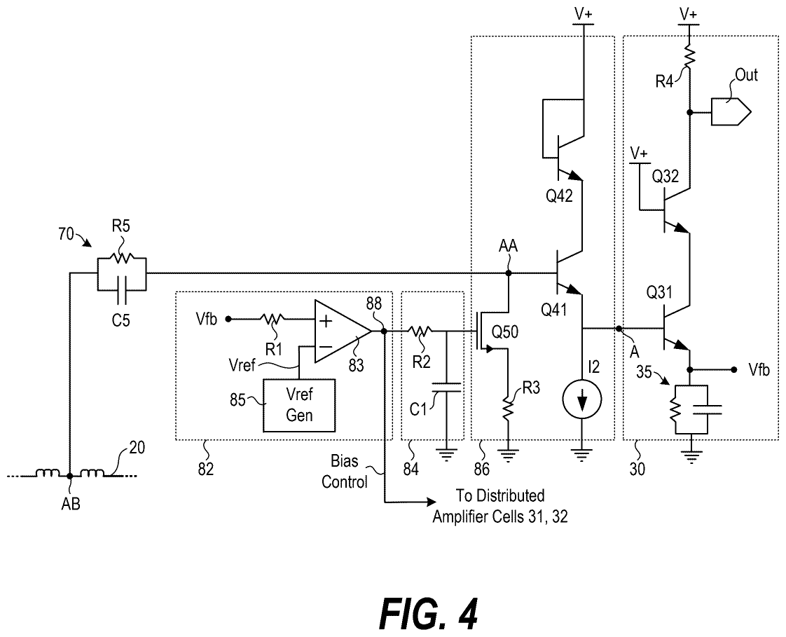

The resistive path in the input coupling networks 70-72 can result in inter-stage amplifier biasing problems, particularly if the DC bias needed at the collector of the auxiliary transistor Q21 is different than the DC bias needed at the inputs to the distributed amplifier cells 30-32. The distributed amplifier stage 14A includes bias adjustment circuitry 80 to address any inter-stage amplifier biasing problems between the auxiliary transistor Q21 and the distributed amplifier cells 30-32. The structure and operation of the bias adjustment circuitry 80 is described in further detail below with reference to FIG. 4. In summary, the bias adjustment circuitry 80 is configured to control an amplifier input bias, and particularly the DC input bias, provided at an input node “A” of the distributed amplifier cell 30. The bias adjustment circuitry 80 is also configured to control the DC input bias provided at the input nodes “B” and “C” of the distributed amplifier cells 31 and 32, respectively.

In one example, to control the DC input bias at the input node “A” of the distributed amplifier cell 30, the bias adjustment circuitry 80 is configured to control the voltage drop or potential difference across the resistor in the input coupling network 70. To control the DC input bias at the node “B” of the distributed amplifier cell 31, the bias adjustment circuitry 80 is configured to control the voltage drop or potential difference across the resistor in the input coupling network 71. To control the DC input bias at the node “C” of the distributed amplifier cell 32, the bias adjustment circuitry 80 is configured to control the voltage drop or potential difference across the resistor in the input coupling network 72.

The bias adjustment circuitry 80 can operate based on feedback from one or more of the distributed amplifier cells 30-32. In the example shown in FIG. 3, the bias adjustment circuitry 80 takes a voltage feedback signal Vfb from the distributed amplifier cell 30. The voltage feedback signal Vfb can be taken from a terminal of the distributed amplifier cell 30, such as a common or output terminal of a transistor in the distributed amplifier cell 30. Alternatively, the voltage feedback signal Vfb can be taken from a common or output terminal of the distributed amplifier cell 31 or the distributed amplifier cell 32. In another example, the voltage feedback signal Vfb can be gathered (e.g., using a resistor network) from terminals of two or more of the distributed amplifier cells 30-32. These and other aspects of the bias adjustment circuitry 80 are described below with reference to FIG. 4.

FIG. 4 illustrates the distributed amplifier cell 30 of the amplifier 10A shown in FIG. 3 with bias adjustment circuitry. The bias adjustment circuitry includes a bias control circuit 82, an RF bypass circuit 84, and a bias interface circuit 86 in the example shown. The bias control circuit 82, RF bypass circuit 84, and bias interface circuit 86 are, collectively, one example of the bias adjustment circuitry 80 shown in FIG. 3 and described above. FIG. 4 also depicts one example of the distributed amplifier cell 30, but the concepts of bias control for distributed amplifiers can be applied to other topologies and types of distributed amplifier cells. The concepts of bias control for distributed amplifiers can be applied using and extended to other circuits, and one or more of the distributed amplifier cell 30, bias control circuit 82, RF bypass circuit 84, and bias interface circuit 86 can vary in some cases.

The distributed amplifier cell 30 includes transistors Q31 and Q32 and a termination network 35 in the example shown. The transistor Q31 is configured as an emitter follower transistor, having an input node “A” at a base terminal, a collector terminal coupled to an emitter of the transistor Q32, and an emitter terminal coupled to the termination network 35. The transistor Q32 is configured as a common base transistor, with a base terminal coupled to a bias potential V+, a collector terminal coupled to an upper rail voltage or potential V+ through a resistor R4, and an emitter terminal coupled to the collector terminal of the transistor Q31. An output “Out” of the distributed amplifier 30 is taken from the collector terminal of the transistor Q32. The bias potential V+ at the base of the transistor Q32 can vary, depending on design needs, and the bias potential V+ at the base of the transistor Q32 can be different than the upper rail voltage V+. The transistor Q32 can also be a diode connected transistor in some cases, and the distributed amplifier cell 30 can vary in other ways depending on design needs.

The bias adjustment circuitry includes a bias control circuit 82, an RF bypass circuit 84, and a bias interface circuit 86. As noted above, the bias control circuit 82, RF bypass circuit 84, and bias interface circuit 86 are, collectively, one example of the bias adjustment circuitry 80 shown in FIG. 3. The bias adjustment circuitry shown in FIG. 4 supports the establishment of a DC bias at an input of the distributed amplifier cell 30, as described below. The bias adjustment circuitry shown in FIG. 4 can also be relied upon, at least in part, to establish DC biases at inputs of the distributed amplifier cells 31 and 32, using the bias control signal 88 generated by the bias control circuit 82.

The bias control circuit 82 includes a resistor R1, an operational or difference amplifier 83, and a voltage reference generator 85. The bias control circuit 82 operates based on the voltage feedback signal Vfb, which is taken from the distributed amplifier cell 30. The voltage feedback signal Vfb is taken from the emitter terminal of the transistor Q31, which is a common terminal of the transistor Q31, as depicted in FIG. 4. In other cases, the voltage feedback signal Vfb can be taken from the output “Out” or another node or terminal of the distributed amplifier cell 30. In still other cases, the voltage feedback signal Vfb can be taken from a terminal of one or more of the distributed amplifier cells 31 and 32 (see FIG. 3). The voltage feedback signal Vfb can also be gathered from terminals of two or more of the distributed amplifier cells 30-32.

The difference amplifier 83 receives the feedback signal Vfb at a non-inverting input and receives a reference voltage Vref generated by the voltage reference generator 85 at an inverting input. The difference amplifier 83 is configured to compare the reference voltage Vref and the feedback signal Vfb and generate the bias control signal 88 based on a difference or comparison of Vref and Vfb. The bias control signal 88 is representative of the difference between the reference voltage Vref and the feedback signal Vfb. The control loop provided by bias control circuit 82 acts to minimize or reduce the difference between Vref and Vfb, based on a desired or target DC bias at the input node “A” of the distributed amplifier cell 30.

Thus, the bias control signal 88 is a control signal used to set the DC bias at an input of the distributed amplifier cell 30, as described herein. The bias control signal 88 can also be used to set the DC bias at the input nodes “B” and “C” of the distributed amplifier cells 31 and 32, as schematically shown in FIG. 3. For example, each of the distributed amplifier cells 31 and 32 can also include an RF bypass circuit similar to the RF bypass circuit 84 and a bias interface circuit 86 similar to the bias interface circuit 86. The bias control signal 88 can be provided to those RF bypass and bias interface circuits to set the DC biases at the input nodes “B” and “C” of the distributed amplifier cells 31 and 32.

The voltage reference generator 85 can be embodied using current mirrors, resistances, and other circuit components capable of generating the reference voltage Vref with suitable precision, preferably over different operating voltages, temperature ranges, etc. In some cases, the voltage reference generator 85 can be programmable or controllable, to generate one or more different reference voltages over time, or a range of reference voltages over time. Based on the operation of bias control circuit 82, the DC bias at the input node “A” of the distributed amplifier cell 30 will track the reference voltage Vref. Thus, the DC bias potential for the distributed amplifier cell 30 at the input node “A” can be set based on the reference voltage Vref generated by the voltage reference generator 85. The voltage reference generator 85 can be configured to maintain a desired or target reference voltage Vref, even over a range of process variations, voltage, and temperature variations for the amplifier 10A during operation.

The bias control signal 88 is provided to the RF bypass circuit 84, which includes the capacitor C1 and the resistor R2. The capacitor C1 provides an RF short to ground for high-frequency components on the bias control signal 88. The capacitance of C1 can be selected based on the operating frequency range of the amplifier 10A. The resistor R2 provides an impedance to limit transient current flow. The RF bypass circuit 84 can also be omitted in some cases, in which case the bias control signal 88 can be provided directly to the bias interface circuit 86.

The bias interface circuit 86 includes transistors Q41, Q42, and Q50, resistor R3, and current source I2 in the example shown. The transistor Q41 is configured as an emitter follower transistor, having an input node at a base terminal, a collector terminal coupled to an emitter of the transistor Q42, and an emitter terminal coupled to the current source I2. The base terminal of the transistor Q41 is coupled, at the node “AA”, through the input coupling network 70 to the transmission line 20. The emitter terminal of the transistor Q41 is also coupled to the input node “A” of the distributed amplifier cell 30. The transistor Q42 is diode connected, having electrically coupled base and collector terminals, and the collector terminal of Q42 is coupled to the upper rail voltage or potential V+. The potential V+ at the collector terminal of Q42 can be the same as or different than the potential V+ at the collector terminal of Q32.

The transistor Q50, which can be embodied as a FET transistor, has a drain terminal coupled to the node “AA,” which is between the base terminal of the transistor Q41 and the input coupling network 70. The transistor Q50 also has a source terminal coupled to the resistor R3, and a gate terminal coupled to the bias control signal 88 through the RF bypass circuit 84.

The bias interface circuit 86 is configured to transfer the DC bias potential at the “AA” node to the input node “A” of the distributed amplifier cell 30 (with a Vbe potential drop across the transistor Q41). The bias interface circuit 86 is also configured to isolate the distributed amplifier cell 30 from the bias adjustment circuitry.

In operation, the bias control signal 88 is provided to the gate of the transistor Q50. The transistor Q50 will sink current from the “AA” node based on the bias control signal 88, until the Vref and Vfb voltages converge. The bias interface circuit 86 then transfers the DC bias potential at the “AA” node to the input node “A” of the distributed amplifier cell 30, to set the DC bias and operating point of the Q31 transistor of the distributed amplifier 30.

The input coupling network 70 is positioned and coupled between the “AB” node along the transmission line 20 and the “AA” node at the base terminal of the transistor Q41. The input coupling network includes the resistor R5 and the capacitor C5, which are coupled in parallel with each other. The input coupling network 70 provides two signal paths between the transmission line 20 and the distributed amplifier cell 30, including a resistive path through the resistor R5 for lower frequencies down to direct current (e.g., down to DC) and a capacitive path through the capacitor C5 for higher frequencies. As noted above, the inclusion of the resistor R5 in the input coupling network 70 facilitates lower frequency operation of the distributed amplifier cell 30.

The DC bias at the “AB” node is the same DC bias at the collector of the auxiliary transistor Q21 of the variable gain amplifier 12 (see FIG. 3). The DC bias at the “AA” node, on the other hand, can be different than at the “AA” node, depending on the voltage drop across the resistor R5. The DC bias at the “AA” node is then transferred through the bias interface circuit 86 to the node “A” at the input of the distributed amplifier cell 30. The DC bias at the “AB” node is controlled based on the amount or extent of current sunk by the transistor Q50, which is based on the bias control signal 88 provided from the difference amplifier 83. Thus, the bias control circuit 82 is configured to control the voltage drop across the resistor R5, the DC bias at the “AB” node, and the DC bias at the “A” node of the distributed amplifier cell 30.

The transistors described herein, including the transistors Q11, Q12, Q21, Q22, Q31, Q32, Q41, Q42, and Q50 can be implemented as a range of different types of transistors formed in a range of different semiconductor materials. The transistors can be formed as bipolar junction transistors, FETs, variants thereof, and other types of transistors, and the concepts can be applied to a range of transistor types. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates. The transistors can be implemented in silicon germanium (SiGe), gallium arsenide (GaAs), gallium nitride (GaN), GaN materials, and other semiconductor materials on or over a range of different substrates. As non-limiting examples, the transistors can be structured as enhancement or depletion mode FET transistors, such as a depletion mode GaAs pHEMT transistors, as GaN HEMT transistors, as GaN materials HEMT transistors, or as related power transistors.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. An amplifier with input bias control comprising:
a distributed amplifier cell comprising an input coupled to a first distributed transmission line and an output coupled to a second distributed transmission line;
an input coupling network coupled between the first distributed transmission line and the input of the distributed amplifier cell; and
a bias interface circuit coupled between the input coupling network and the input of the distributed amplifier cell.

2. The amplifier according to claim 1, wherein the bias interface circuit comprises an emitter follower transistor.

3. The amplifier according to claim 2, wherein the bias interface circuit comprises an emitter follower transistor and a sink transistor coupled to a base terminal of the emitter follower transistor.

4. The amplifier according to claim 1, further comprising a bias control circuit configured to control an amplifier input bias generated by the bias interface circuit at the input of the distributed amplifier cell.

5. The amplifier according to claim 4, wherein:
the bias interface circuit comprises an emitter follower transistor and a sink transistor coupled to a base terminal of the emitter follower transistor; and
the bias control circuit is further configured to control the sink transistor to set an input bias of the emitter follower transistor.

6. The amplifier according to claim 4, wherein:
the bias interface circuit comprises an emitter follower transistor and a sink transistor coupled to a base terminal of the emitter follower transistor; and
the bias control circuit is further configured to control the sink transistor to establish a potential difference across the input coupling network.

7. The amplifier according to claim 4, wherein:
the bias interface circuit comprises an emitter follower transistor and a sink transistor coupled to a base terminal of the emitter follower transistor;
the bias control circuit comprises a difference operational amplifier and a reference voltage generator;
an output of the reference voltage generator is coupled to a first input of the difference operational amplifier;
a common terminal of the distributed amplifier cell is coupled to a second input of the difference operational amplifier; and
an output of the difference operational amplifier is coupled to the sink transistor.

8. The amplifier according to claim 4, further comprising:
a second distributed amplifier cell comprising an input coupled to the first distributed transmission line and an output coupled to the second distributed transmission line;
a second input coupling network coupled between the first distributed transmission line and the input of the second distributed amplifier cell; and
a second bias interface circuit coupled between the second input coupling network and the input of the second distributed amplifier cell, wherein:
a bias control circuit is further configured to control an amplifier input bias generated by the second bias interface circuit at the input of the second distributed amplifier cell.

9. The amplifier according to claim 1, wherein the input coupling network comprises a resistive-capacitive network.

10. The amplifier according to claim 1, wherein:
the amplifier comprises a multi-stage amplifier; and
the distributed amplifier cell is coupled to an output of a variable gain amplifier stage of the multi-stage amplifier.

11. An amplifier with input bias control comprising:
a distributed amplifier cell;
an input coupling network coupled between a distributed transmission line and an input of the distributed amplifier cell; and
a bias interface circuit coupled to the input of the distributed amplifier cell.

12. The amplifier according to claim 11, wherein the bias interface circuit comprises a sink transistor coupled between the distributed transmission line and an input of the distributed amplifier cell.

13. The amplifier according to claim 12, further comprising a bias control circuit configured to control the sink transistor to set an input bias of the distributed amplifier cell.

14. The amplifier according to claim 13, wherein the bias control circuit is further configured to control the sink transistor to establish a potential difference across the input coupling network.

15. The amplifier according to claim 13, wherein:
the bias control circuit comprises a difference operational amplifier and a reference voltage generator;
an output of the reference voltage generator is coupled to a first input of the difference operational amplifier;
a common terminal of the distributed amplifier cell is coupled to a second input of the difference operational amplifier; and
an output of the difference operational amplifier is coupled to the sink transistor.

16. The amplifier according to claim 13, further comprising:
a second distributed amplifier cell;
a second input coupling network coupled between the distributed transmission line and an input of the second distributed amplifier cell; and
a second bias interface circuit coupled between the second input coupling network and the input of the second distributed amplifier cell, wherein:
the bias control circuit is further configured to control an amplifier input bias generated by the second bias interface circuit at the input of the second distributed amplifier cell.

17. A amplifier with input bias control comprising:
a first distributed amplifier cell and a second distributed amplifier cell;
a first input coupling network coupled between a distributed transmission line and an input of the first distributed amplifier cell;
a second input coupling network coupled between the distributed transmission line and an input of the second distributed amplifier cell;
a first bias interface circuit coupled to the input of the first distributed amplifier cell; and
a second bias interface circuit coupled to the input of the second distributed amplifier cell.

18. The amplifier according to claim 17, wherein:
the first bias interface circuit comprises a first sink transistor coupled between the distributed transmission line and the input of the first distributed amplifier cell; and
the second bias interface circuit comprises a second sink transistor coupled between the distributed transmission line and the input of the second distributed amplifier cell.

19. The amplifier according to claim 18, further comprising a bias control circuit configured to control the first sink transistor to set an input bias of the first distributed amplifier cell and to control the second sink transistor to set an input bias of the second distributed amplifier cell.

20. The amplifier according to claim 19, wherein the bias control circuit is further configured to control the first sink transistor to establish a potential difference across the first input coupling network and to control the second sink transistor to establish a potential difference across the second input coupling network.
